(19) United States
(12) Patent Application Publication
(10) Pub. No.: US 2005/0101143 A1
(43) Pub. Date: May 12, 2005

(54) Methods of fabricating a semiconductor device and forming a trench region in a semiconductor device

(76) Inventors: Seung-Jae Lee, Suwon-si (KR); Min Kim, Seoul (KR); Jai-Dong Lee, Suwon-si (KR); Kyoung-Seok Kim, Seoul (KR); Hyeon-Deok Lee, Seoul (KR); Ju-Bum Lee, Hwaseong-gun (KR); Hun-Hyeoung Leam, Yongin-si (KR)

Correspondence Address: HARNESS, DICKEY & PIERCE, P.L.C., P.O. BOX 8910, RESTON, VA, 20195, US

(21) Appl. No.: 10/911,730

(22) Filed: Aug. 5, 2004

(30) Foreign Application Priority Data
Nov. 11, 2003 (KR) 2003-79590

(51) Int. Cl. H01L 21/311

(52) U.S. Cl. 438/700

(57) ABSTRACT

In a method of forming a shallow trench isolation (STI) region in a semiconductor device, a pad oxide layer and a pad nitride layer may be formed on a semiconductor substrate. The pad nitride layer and pad oxide layer may be patterned to form an isolation region with exposed portions on the pad nitride layer, pad oxide layer and semiconductor substrate. A radical oxide layer may be formed on the exposed portions, and a trench may be formed in the isolation region by etching the semiconductor substrate and radical oxide layer. The STI region may be formed by filling an insulating layer in the trench.

### PRIORITY STATEMENT

This application claims the priority of Korean Patent Application No. 2003-79590, filed on Nov. 11, 2003, in the Korean Intellectual Property Office, the disclosure of which is incorporated herein in its entirety by reference.

### BACKGROUND OF THE INVENTION

1. Field of the Invention

The present invention relates to a method of fabricating a semiconductor device and to a method of forming a shallow trench isolation (STI) region in a semiconductor device.

2. Description of the Related Art

As semiconductor device integration becomes evermore prevalent and feature size becomes reduced, an isolation region of a semiconductor device may also be reduced. An isolation process is an initial process of a semiconductor device manufacturing process, and may be a factor in determining the size of an active region in the device and/or the process margin in a subsequent fabrication process. Recently, in manufacturing highly integrated semiconductor devices, a ‘shallow trench isolation’ process (STI) has generally been used for the isolation process.

In the STI process, an insulator such as a high density plasma (HDP) silicon oxide may be filled in a trench that has been formed in a silicon substrate to form an isolation layer, i.e., an STI region. By using the STI process, an area occupied by the isolation layer can be reduced. It may be possible to substantially reduce stress applied to the silicon substrate by improving the manufacturing process and the material and structure of the STI region.

FIG. 1 is a SEM photograph showing an edge profile of an active region of a semiconductor device fabricated according to a prior art fabrication process. In a semiconductor device having an STI structure, an edge profile of the active region may substantially influence the electrical properties and reliability of a semiconductor device such as a transistor. Referring to FIG. 1, for example, if the edge portion of the active region is damaged during the STI process and the edge portion becomes sharp, as shown in FIG. 1, a substantial junction leakage current may be generated. Semiconductor device reliability may be reduced due to this junction leakage current. On the other hand, if the edge profile is rounded, the leakage current characteristic may be acceptable, and accordingly, the semiconductor device reliability may be superior.

The edge profile of the active region may also have a substantial influence on dispersion and/or fluctuation of a threshold voltage of a memory cell. In other words, if the edge portion of the active region is not rounded and/or is damaged, the range of the threshold voltage may be raised and/or there may be threshold voltages which may be too high and/or too low.

Thus, if the width of a scattering graph (which is a graph of threshold voltage as a function of the number of memory cells) is widened, or a tail is produced due to the fluctuation in threshold voltage, reliability of a memory cell configuration such as flash memory, i.e., NAND-type flash memory having substantially high integration, may be reduced. For example, in the case of a flash memory device capable of storing 2 bits data in a unit cell, it may be desirable to reduce the range of the threshold voltage and/or prevent extreme threshold voltages.

In an effort to solve problems due to damaged edge portions of the active region, and in an effort to provide a rounded isolation region is rounded, several methods have been proposed. For example, one prior art fabrication process may prevent damage of the edge portion by adding a doped polysilicon layer between the pad oxide layer and the nitride layer. Another fabrication method may manufacture a semiconductor device with a protected edge portion of an active region (and a rounded isolation region) by forming an undercut in a polysilicon layer that has been formed between a pad oxide layer and a nitride layer. However, since these prior art processes add a process of forming the polysilicon layer, production costs and production time may be increased. Also, since the prior art processes employ isotropic wet etch processes, it may be difficult to perform the wet etch process in-situ with pre- and/or post-processes.

### SUMMARY OF THE INVENTION

In general, the exemplary embodiments are directed to methods of fabricating a semiconductor device and to methods of forming a shallow trench isolation (STI) region in a semiconductor device. In an example, a pad oxide layer and a pad nitride layer may be formed on a semiconductor substrate. The pad nitride layer and pad oxide layer may be patterned to form an isolation region with exposed portions on the pad nitride layer, pad oxide layer and semiconductor substrate. A radical oxide layer may be formed on the exposed portions, and a trench may be formed in the isolation region by etching the semiconductor substrate and radical oxide layer. The STI region may be formed by filling an insulating layer in the trench.

### BRIEF DESCRIPTION OF THE DRAWINGS

The present invention will become more apparent by describing, in detail, exemplary embodiments thereof with reference to the attached drawing, wherein like elements are represented by like reference numerals, which are given by way of illustration only and thus do not limit the exemplary embodiments of the present invention.

FIG. 1 is a SEM photograph showing an edge profile of an active region of a semiconductor device fabricated according to a prior art fabrication process.

FIGS. 2A through 2F are cross-sectional views illustrating a method of forming an STI region of a semiconductor device according to an exemplary embodiment of the present invention.

FIGS. 3A through 3C are SEM photographs showing intermediate stages of a method of forming an STI region of a semiconductor device according to an exemplary embodiment of the present invention.

FIG. 4 is a graph showing a radius variation in an edge profile rounding of an active region according to a thickness of the radical oxide layer.

FIG. 5 is a graph showing a scattering of a threshold voltage according to a thickness of the radical oxide layer.

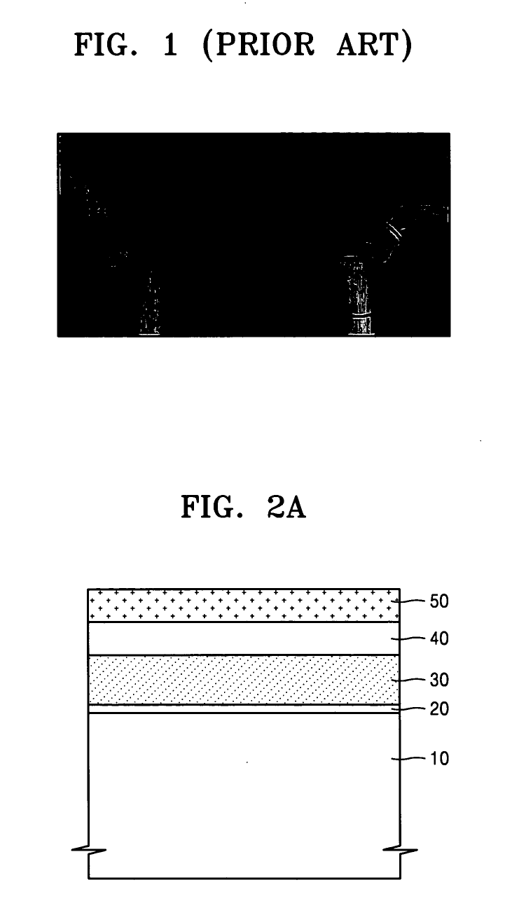

### DETAILED DESCRIPTION OF THE EXEMPLARY EMBODIMENTS

The present invention will be described more fully with reference to the accompanying drawings, in which exemplary embodiments of the invention are shown. It should be understood, however, that exemplary embodiments of the present invention described herein can be modified in form and detail without departing from the spirit and scope of the invention. Accordingly, the exemplary embodiments described herein are provided by way of example and not of limitation, and the scope of the present invention is not restricted to the particular embodiments described herein.

In particular, the relative thicknesses and positioning of layers or regions may be reduced or exaggerated for clarity. Further, a layer is considered as being formed “on” another layer or a substrate when formed either directly on the referenced layer or the substrate or formed on other layers or patterns overlaying the referenced layer.

In the following description, it will be appreciated that the figures may not be not drawn to scale. Rather, for simplicity and clarity of illustration, the dimensions of some elements may be exaggerated relative to other elements. Like reference numerals and characters may be used for like and corresponding elements of the various drawings.

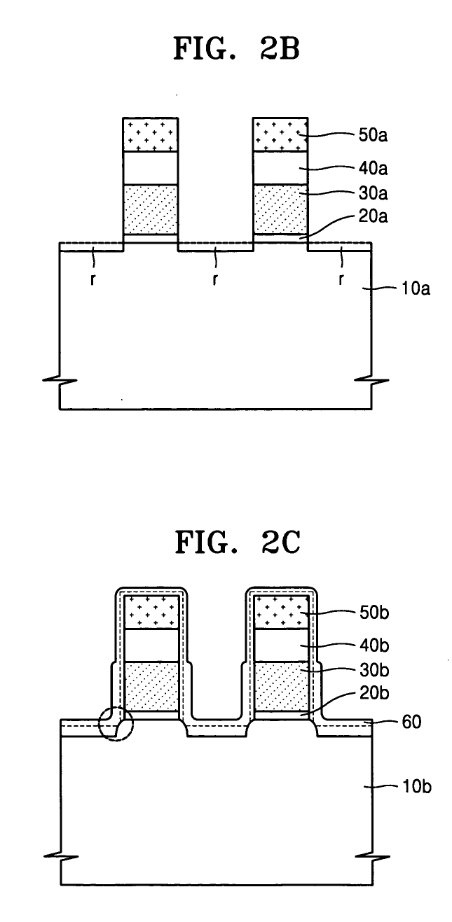

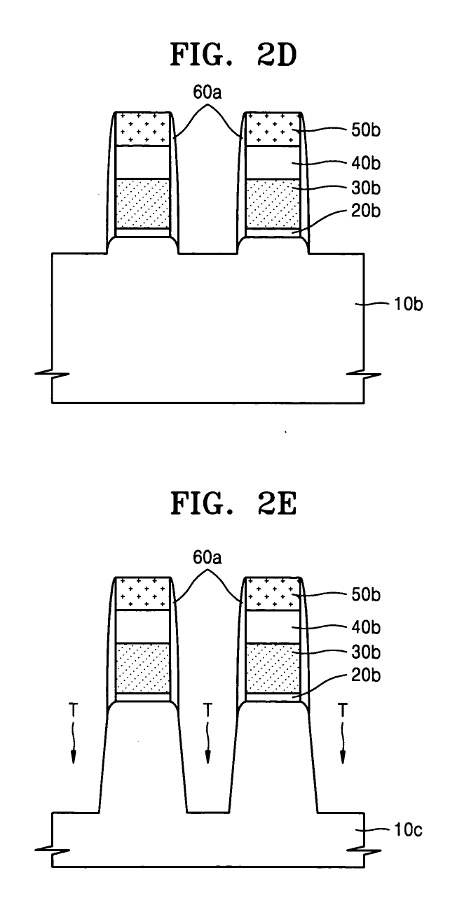

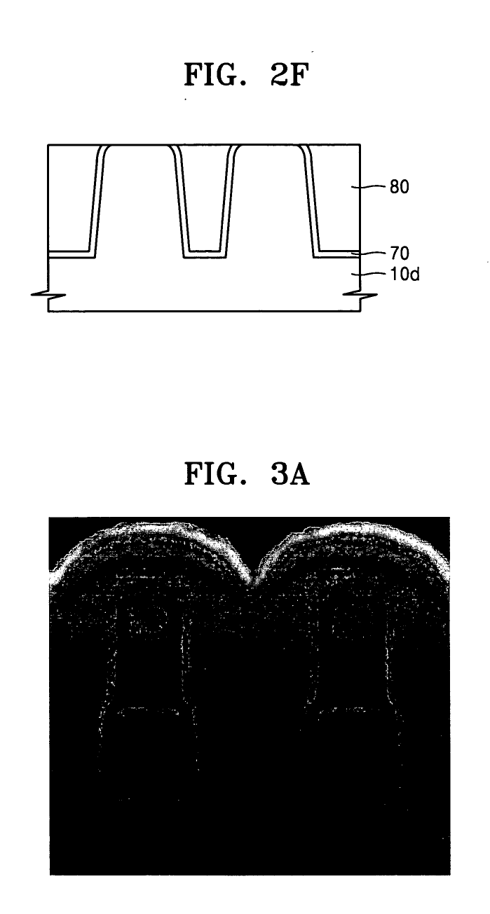

FIGS. 2A through 2F are cross-sectional views illustrating a method of forming an STI region of a semiconductor device according to an exemplary embodiment of the present invention. Referring to FIG. 2A, a pad oxide layer 20, a pad nitride layer 30, a first hard mask layer 40 and a second hard mask layer 50 may be sequentially formed on a semiconductor substrate 10 such as a silicon substrate, for example.

The pad oxide layer 20 may reduce stress between the semiconductor substrate 10 and the pad nitride layer 30, and may be formed to a thickness of about 100 Å, although 100 Å is merely an exemplary thickness. The pad oxide layer 20 may be greater or less than 100 Å.

The pad nitride layer 30 may function as an etch mask in a process of etching the semiconductor substrate 10. Additionally, the pad nitride layer 30 may function as an etch stopper in a subsequent chemical mechanical polishing (CMP) process. The pad nitride layer 30 can be formed to a thickness in a range of about 600 to 850 Å, although this is merely an exemplary thickness range. The pad nitride layer 30 may have a thickness less than 600 Å or greater than 850 Å, depending on the application and size requirements of the device, for example.

The first hard mask layer 40 and second hard mask layer 50 may function as an etch mask in the process of etching the semiconductor substrate 10 for the formation of the STI region. Accordingly, in an example where only the pad nitride layer 30 is used as the etch mask for the trench etching process, the forming of the first and second hard mask layers 40 and 50 may be omitted. The first and second hard mask layers 40 and 50 may include a composite layer of a medium temperature oxide (MTO) layer 40 having a thickness of about 400 Å and a siliconoxynitride layer 50 having a thickness of about 400 Å, although these are exemplary thicknesses; other thicknesses may be possible as is evident to those having ordinary skill in the art. Alternatively, one of the MTO layer 40 and siliconoxynitride layer 50 may be omitted.

The pad nitride layer 30 and the first and second hard mask layers 40 and 50 may be deposited by a suitable deposition process. For example, the pad nitride layer 30 and the first and second hard mask layers 40 and 50 may be deposited by a chemical vapor deposition (CVD) process, a low pressure chemical vapor deposition (LPCVD) process, a plasma enhanced chemical vapor deposition (PECVD) process, etc.

Referring to FIG. 2B, the first and second hard mask layers 40 and 50, the pad nitride layer 30 and the pad oxide layer 20 may be patterned to form first and second hard mask patterns 40a and 50a, a pad nitride pattern 30a and a pad oxide pattern 20a. This may be performed by a photolithography process.

For example, a photoresist pattern (not shown) defining an active region may be formed on the siliconoxynitride layer 50. The siliconoxynitride layer 50 may be anisotropically dry-etched using the photoresist pattern as an etch mask to form the first and second hard mask patterns 40a and 50a. The photoresist pattern may then be removed, and anisotropic dry etching may again be performed using the first and second hard mask patterns 40a and 50a as an etch mask, so as to form the pad nitride pattern 30a and the pad oxide pattern 20a. Some overetch may be performed to finalize the formation of the pad nitride pattern 30a and the pad oxide pattern 20a. As a result of the overetch, a recess ‘r’ may be formed in the semiconductor substrate 10a in the isolation region, as shown in FIG. 2B, for example. Optionally during the patterning process to form the respective patterns 20a-50a and the isolation region on substrate 10a, the pad oxide layer 20 may be etched so as to form an undercut (not shown for reasons of clarity) below the pad nitride layer 30.

Referring to FIG. 2C, a radical oxidation process may be performed on the resultant structure of FIG. 2B. The radical oxidation process may be performed in a batch type facility and/or in a single wafer type facility, for example. In the radical oxidation process, oxygen gas and/or hydrogen gas and/or hydrogen chloride gas may be used as the source gas. The radical oxidation process may be performed at a relatively low pressure. For example, the radical oxidation process may be performed at a pressure in a range from about a few about 5 mTorr to about 50 Torr, and at a temperature of about 600° C. to 1100° C., so as to activate the source gas in a radical state. Since the radical oxidation may accelerate the oxidation reaction, regardless of the kind and profile of a material layer to be oxidized, it may be possible to form an oxide layer having a substantially uniform or uniform thickness over an entire portion (including an edge portion having a sharp profile) due to the recess r.

If a dry thermal oxidation process or a wet thermal oxidation process is performed, the degree of the oxidation reaction may depend on the kind of material layer to be oxidized, and the oxide may be formed thinner at an edge portion which has a sharp profile, as compared with other portions of the active region. However, according to the exemplary embodiments, although a sharp edge portion may exist, it may possible to form an oxide layer having a substantially uniform or uniform thickness over the entire surface, as shown in FIG. 2C.

As a result of the radical oxidation process, a radical oxide layer 60 may be formed to a given thickness on exposed surfaces of the semiconductor substrate 10a, the pad oxide pattern 20a, the pad nitride pattern 30a, and the first and second hard mask patterns 40a and 50a. The thickness of the radical oxide layer 60 may not be completely uniform, depending on the kind of material layer and/or the position of the material layer to be oxidized, but may exhibit a substantially uniform thickness characteristic.

For example, the radical oxide layer 60 may be about 30 to 300 \check{A} thick, and in another example, about 50 to 200 \check{A} thick. Also, at a contact portion between the semiconductor substrate 10b and the pad oxide pattern 20b, a ‘bird's beak’ phenomenon may occur during the formation of the radical oxide layer 60. In general in accordance with this phenomenon, and typically during an oxidation process such as described above, a structure may be formed by lateral diffusion along an exposed interface, resulting in a tapered growth profile which may extend under a given layer, such as a blocking layer, for example. Thus, due to the bird's beak phenomenon, the edge profile of the active region may be rounded, as indicated by the dotted-line circle in FIG. 2C.

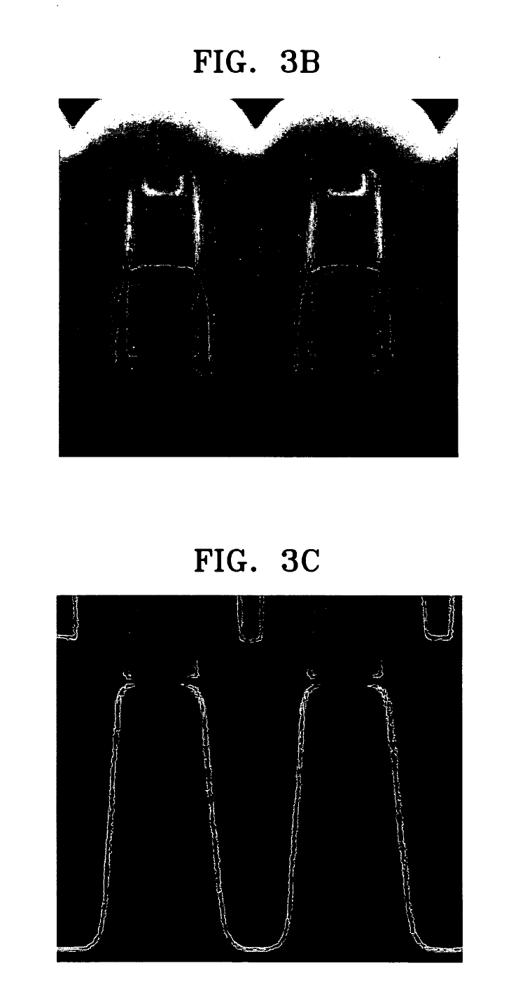

A SEM photograph showing the result of FIG. 2C is illustrated in FIG. 3A. FIG. 3A may correspond to a case where the radical oxide layer 60 may be formed to a thickness of about 150 \check{A}, this thickness being merely exemplary, other thicknesses may be possible to those of ordinary skill in the art. Referring to FIG. 3A, the edge profile of the active region may be rounded and the radical oxide layer 60 may be formed to a wider thickness in the vicinity at an edge of the active region and the sidewall of pad nitride pattern 30b, as shown in FIGS. 2C and 3A, for example.

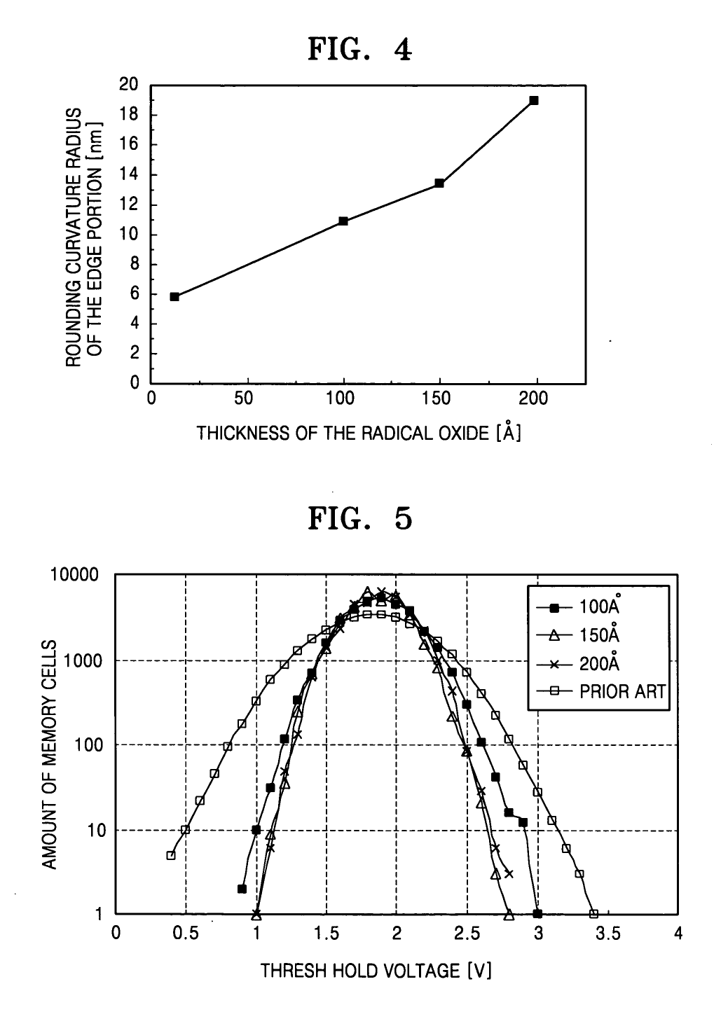

FIG. 4 shows a graph illustrating a variation in the rounding curvature radius of the edge portion with respect to the thickness variation. Although not shown in the drawing, the rounding curvature radius caused by a general thermal oxidation process used in the related art was about 4 nm. However, in accordance with the exemplary embodiments, it can be seen that the rounding curvature radius may be substantially larger, and may increase as the thickness of the radical oxide layer increases, i.e., as the period of radical oxidation process is increased. For example, when the thickness of the radical oxide layer is about 150 \check{A}, the curvature radius is about 14 nm.

Referring to FIG. 2D, a trench may then be formed by etching the semiconductor substrate 10b. Prior to etching the semiconductor substrate 10b, the radical oxide layer 60 on the isolation region (the region and/or surfaces covered by the radical oxide layer 60 as shown in FIG. 2C, for example) may be removed by etching. A dry etch process or a wet etch process may be used for etching the radical oxide layer 60. As in a generic spacer forming process, a forming process such as a dry etchback be used. As a result, the semiconductor substrate 10b on the isolation region may be exposed and a radical oxide spacer 60a may be formed on sidewalls of the material patterns 20b, 30b, 40b and 50b, as shown in FIG. 2D, for example.

The radical oxide spacer 60a may protect the edge portions of the active region in the etching of the semiconductor substrate 10b in a subsequent process. Since a width of a trench to be formed may become narrower in the vicinity of the sidewalls of the radical oxide spacer 60a, the area of the active region may increase.

FIG. 3B is a SEM photograph showing the result after the radical oxide layer on the isolation region is removed to form radical oxide spacer 60a. Referring to FIG. 3B (and in reference to FIG. 2D), the radical oxide spacer 60a may be formed on the sidewall of the pad nitride pattern 30b.

Referring to FIG. 2E, the exposed semiconductor substrate 10b may be anisotropically dry-etched using the first and second hard mask patterns 40b and 50b, and using the radical oxide spacer 60a as an etch mask. This etching process may form the aforementioned trench T defining the active region. An upper portion on the first and second hard mask patterns 40b and 50b and the radical oxide spacer 60a may be partially etched during the anisotropic dry etch process, for example. However, according to the exemplary embodiments, since the edge portion of the active region is protected by the radical oxide spacer 60a, no damage is caused to the edge portion of the active region. As a result, the edge portion of the active region may maintain a substantially rounded shape when the trench T is formed.

Referring to FIG. 2F, an insulating material may be filled in the trench T to form an STI region 80. The STI region 80 may be formed by a general forming process. For example, a liner oxide layer 70 may be formed on a surface of the resultant structure of FIG. 2F in which the trench T is formed, thereby protecting the inner walls of the trench T. Thereafter, an insulating material may be deposited on the line oxide layer 70 to fill the inside of the trench T. The insulating material may be formed from a material consisting of an undoped silicate glass (USG), a high density plasma (HDP) oxide, a tetraethylorthosilicate (TEOS) oxide formed by PECVD and/or other oxides formed by PECVD, and/or a combination of one or more of these materials, for example. Among the aforementioned oxides, the HDP oxide may be an exemplary material for the filling the trench T, although other oxides having properties similar to HDP oxide may be used to fill the trench T.

FIG. 3C is a SEM photograph of a trench filled with an HDP oxide. Referring to FIG. 3C (and with occasional references to FIGS. 2E and 2F), after the trench T is formed, the edge portion of the active region may maintain its rounded shape without any damage. This is because the edge portion of the active region may be protected by the radical oxide spacer 60a, as discussed above. In addition, the planarization process of the insulating material may be performed using CMP or an etchback process, for example. As a result, the STI region 80 may be formed in the trench T, as shown in FIG. 2F.

FIG. 5 is a graph illustrating a distribution of the threshold voltage with respect to the thickness variation of the radical oxide layer. In the key of the graph of FIG. 5, there is a curve representing a device where the thickness of the radical oxide layer is 0 Å (i.e., no radical oxide layer). This curve corresponds to an example of a device in which a trench is formed according to a prior art process. Additionally, there is illustrated curves for three different radical oxide layer thicknesses (100 Å, 150 Å and 200 Å) used in the trench forming process according to the exemplary embodiments of the present invention was used. Referring to FIG. 5, a device having a trench formed with the prior art forming process has threshold voltages ranging over about 3 V. However, when a device with the radical oxide layer is formed according to the exemplary embodiments, threshold voltages may range over about 2 V or less. For example, when the radical oxide layer is 150 Å thick, the range of threshold voltages is reduced to about 1.8 V (between about 1.0 to 2.8 V).

Another exemplary embodiment of the present invention may be directed to a method of fabricating a semiconductor device. This exemplary embodiment may be somewhat similar to the previous exemplary embodiments, thus FIGS. 2A-2F are occasionally referred to hereafter for reasons of brevity. A first layer and a second layer may be sequentially formed on a substrate, similar to as shown in FIG. 2A, for example with regard to layers 20 and 30. Optionally, additional mask layers or a composite mask layer may be formed on the second layers, similar to as shown in FIG. 2A with respect to hard mask layers 40 and 50.

The first and second layers may be patterned to form islands of first and second layers on the substrate with an isolation region having exposed portions formed between the islands on the substrate. For example, the islands may be represented by the patterned layers in FIG. 2B. The isolation region may be represented by the space between the islands, and/or may include exposed surfaces or portions of the substrate 10a and layers 20a-50a in FIG. 2B for example. The patterning may include etching the first layer and the second layer so that the isolation region is recessed into the semiconductor substrate, as shown in FIGS. 2B and/or 2C, for example. Optionally during the patterning process, the first layer may be etched so as to form an undercut below the second layer, as discussed previously with respect to FIG. 2B, for example.

A radical oxide layer, such the radical oxide layer 60 in FIG. 2C, may be formed on one or more of the exposed portions. This may be done by performing a radical oxidation process on the first layer and second layer, for example, similar to as previously described with respect to FIG. 2C. A trench may be formed in the isolation region between the islands, as shown in FIG. 2E, for example. The trench may be filled with an insulating layer to substantially complete device fabrication, as shown in FIG. 2F, for example.

As discussed in previous exemplary embodiments, and prior to etching the semiconductor substrate and radical oxide layer to form the trench, the radical oxide layer may be etched so that the isolation region on the semiconductor substrate is exposed and a radical oxide spacer is formed on sidewalls of the islands, as shown in FIG. 2D, for example.

According to the exemplary embodiments of the present invention, it may be possible to form a shallow trench isolation (STI) region in a semiconductor device, and/or fabricate a semiconductor device, such that the edge profile of the active region is substantially rounded with a larger curvature radius than obtainable by prior art forming processes. Accordingly, an acceptable leakage current characteristic in the edge portion of the active region may be possible, and the reliability of a gate oxide formed in a subsequent process may be enhanced.

Additionally, since damage of the edge portion may be possibly prevented by the formation of a radical oxide layer such as a radical oxide spacer 60a, no damage is caused to the edge portion of the active region, and the range of threshold voltage may be kept relatively small (as shown in FIG. 5) throughout the entire area of the semiconductor memory device. Accordingly, the reliability of the formed semiconductor device may be enhanced. For example, the exemplary methodologies may be used to fabricate a NAND type flash memory capable of storing 2 bits of information in a unit cell. Further, by using the exemplary methodologies described herein for forming an STI region, it may be possible to enlarge the area occupied by the active region.

The exemplary embodiments of the present invention being thus described, it will be obvious that the same may be varied in many ways. Such variations are not to be regarded as departure from the spirit and scope of the exemplary embodiments of the present invention, and all such modifications as would be obvious to one skilled in the art are intended to be included within the scope of the following claims.

1. A method of forming a shallow trench isolation (STI) region in a semiconductor device, comprising:
forming, sequentially, a pad oxide layer and a pad nitride layer on a semiconductor substrate;
patterning the pad nitride layer and the pad oxide layer to form an isolation region with exposed portions on the pad nitride layer, pad oxide layer and semiconductor substrate;
forming a radical oxide layer on the exposed portions;
forming a trench in the isolation region by etching the semiconductor substrate and radical oxide layer; and
forming the STI region by filling an insulating layer in the trench.

2. The method of claim 1, wherein forming a radical oxide layer includes performing a radical oxidation process on the pad nitride layer and the pad oxide layer to form the radical oxide layer.

3. The method of claim 2, wherein the radical oxidation process is, performed at a pressure of about 5 Torr or less.

4. The method of claim 2, wherein the radical oxidation process is performed until the radical oxide layer is formed at a thickness in a range of about 50 to 200 Å.

5. The method of claim 4, wherein the radical oxide layer is formed to a thickness of about at least 50 Å on sidewalls of the pad nitride layer.

6. The method of claim 1, wherein patterning includes etching the pad nitride layer and the pad oxide layer so that the isolation region is recessed into the semiconductor substrate.

7. The method of claim 1, further comprising:
etching the radical oxide layer so that the isolation region on the semiconductor substrate is exposed and a radical oxide spacer is formed on sidewalls of the pad nitride layer and the pad oxide layer,
wherein etching the radical oxidation layer is performed prior to etching the semiconductor substrate and radical oxide layer to form the trench.

8. The method of claim 2, wherein the radical oxidation process is performed with a reaction source selected from a group consisting of oxygen gas, a mixture of oxygen gas and hydrogen gas, and a mixture of oxygen gas, hydrogen gas and hydrogen chloride gas.

9. The method of claim 2, further comprising:
etching the pad oxide layer to form an undercut below the pad nitride layer, prior to performing the radical oxidation process.

10. The method of claim 1, wherein forming the STI region further includes:
forming a liner oxide layer in the trench;
depositing the insulating layer on the liner oxide layer;
planarizing the insulating layer until the pad nitride layer is exposed; and
removing the pad nitride layer.

11. A method of forming a shallow trench isolation (STI) region in a semiconductor device, comprising:
forming, sequentially, a pad oxide layer, an etch stopper nitride layer and a hard mask layer on a semiconductor substrate;
patterning the hard mask layer, etch stopper nitride layer and pad oxide layer to form an isolation region with exposed portions on the hard mask layer, etch stopper nitride layer, pad oxide layer and semiconductor substrate;
forming a radical oxide layer on the exposed portions;
forming a trench in the isolation region by etching the semiconductor substrate and radical oxide layer; and
forming the STI region by filling an insulating layer in the trench.

12. The method of claim 11, wherein forming a radical oxide layer includes performing a radical oxidation process on the exposed portions of the pad oxide layer, etch stopper nitride layer, hard mask layer and semiconductor substrate to form the radical oxide layer.

13. The method of claim 11, wherein forming the trench in the isolation region includes using the hard mask layer as an etch mask to etch the semiconductor substrate.

14. The method of claim 11, wherein the hard mask layer is a composite layer including a silicon oxide layer and a siliconoxynitride layer.

15. The method of claim 11, wherein the semiconductor device is a flash EEPROM device.

16. The method of claim 12, wherein the radical oxidation process is performed at a pressure of about 5 Torr or less.

17. The method of claim 12, wherein the radical oxidation is performed until the radical oxide layer is formed at a thickness in a range of about 50 to 200 Å.

18. The method of claim 17, wherein the radical oxidation layer is formed to a thickness of at least 50 Å on sidewalls of the etch stopper nitride layer and the hard mask layer.

19. The method of claim 11, wherein patterning includes etching the, hard mask layer, pad nitride layer and pad oxide layer so that the isolation region is recessed into the semiconductor substrate.

20. The method of claim 11, further comprising:
etching the radical oxidation layer so that the isolation region of the semiconductor substrate is exposed and a radical oxide spacer is formed on sidewalls of the hard mask layer, etch stopper nitride layer and pad oxide layer,
wherein said etching the radical oxide layer is performed prior to etching the semiconductor substrate and radical oxide layer to form the trench.

21. The method of claim 12, wherein the radical oxidation process is performed with a reaction source selected from a group consisting of oxygen gas, a mixture of oxygen gas and hydrogen gas, and a mixture of oxygen gas, hydrogen gas and hydrogen chloride gas.

22. The method of claim 12, further comprising:
etching the pad oxide layer to form an undercut below the etch stopper nitride layer, prior to performing the radical oxidation process.

23. The method of claim 11, wherein forming the STI region further includes:
forming a liner oxide layer in the trench;
depositing an insulating layer on the liner oxide layer;
planarizing the hard mask layer and the insulating layer until the etch stopper nitride layer is exposed; and
removing the etch stopper nitride layer.

24. A method of fabricating a semiconductor device, comprising:
forming a first layer and a second layer sequentially on a substrate;
patterning the first and second layers to form islands of first and second layers on the substrate with an isolation region having exposed portions formed between the islands on the substrate;
forming a radical oxide layer on at least the exposed portions;
forming a trench in the isolation region between the islands; and
filling an insulating layer in the trench.

25. The method of claim 24, wherein forming the radical oxide layer includes performing a radical oxidation process on the first layer and second layer to form the radical oxide layer.

26. The method of claim 25, wherein patterning includes etching the first layer and the second layer so that the isolation region is recessed into the semiconductor substrate.

27. The method of claim 24, further comprising:
etching, prior to etching the semiconductor substrate and radical oxide layer to form the trench, the radical oxide layer so that the isolation region on the semiconductor substrate is exposed and a radical oxide spacer is formed on sidewalls of the islands.

28. The method of claim 25, further comprising:
etching the first layer to form an undercut below the second layer, prior to performing the radical oxidation process.
